(19) United States
(12) Patent Application Publication
(10) Pub. No.: US 2007/0057737 A1
(43) Pub. Date: Mar. 15, 2007

(54) Compensation for modulation distortion

(75) Inventors: Darrell E. Davis, Sunrise, FL (US); Mahibur Rahman, Lake Worth, FL (US)

Correspondence Address: LAW OFFICE OF CHARLES W. BETHARDS, LLP, P.O. BOX 1622, COLLEYVILLE, TX, 76034, US

(73) Assignee: FREESCALE SEMICONDUCTOR, INC.

(21) Appl. No.: 11/226,081

(22) Filed: Sep. 14, 2005

(51) Int. Cl. H03L 7/00

(52) U.S. Cl. 331/17

(57) ABSTRACT

A modulation distortion compensation system for a phase locked loop 109 includes a compensation function (115) that is arranged to be coupled to a tuning voltage signal (117) corresponding to a tuning voltage from the phase locked loop and is configured to select a filter response from a plurality of filter responses, where the filter response corresponds to the tuning voltage. The distortion compensation system further includes a filter 224 that is configured to distort a modulation signal in accordance with the filter response and provide a distorted signal suitable for being coupled to a modulation input 211 of a feedback divider 209 included with the phase locked loop, wherein the distorted signal when used by the feedback divider will facilitate modulation and compensation of a radio frequency signal provided by the phase locked loop. Various environmental measurements in addition to the tuning voltage can also be used in selecting the filter response.

### FIELD OF THE INVENTION

This invention relates in general to communication transmitters and more specifically to compensation for phase locked loop (PLL) modulation distortion in such transmitters.

### BACKGROUND OF THE INVENTION

The use of phase locked loops in transceivers is known. They are normally used together with a crystal oscillator to realize a signal with a frequency that may be varied in accordance with the radio frequency of different communication channels and still maintain the relatively stable frequency drift over time and temperature associated with the crystal oscillator. In systems where information is transferred by the radio frequency signal in the form of phase modulation of the radio frequency signal, a phase locked loop may also be used to induce this modulation on the radio frequency signal.

However when the phase locked loop is directly modulated various problems may be encountered. For example the characteristics of a phase locked loop and the ability to directly modulate the phase locked loop will depend on the loop bandwidth. Other characteristics of a phase locked loop will also depend on the loop bandwidth. For example, the time to switch from one frequency to another (sometimes referred to as lock time) will depend on the phase locked loop bandwidth. Furthermore, the loop bandwidth as well as other loop parameters will influence phase noise levels, etc.

One of the results of these tradeoffs is that a practical phase locked loop may not have a flat amplitude or linear phase response for a modulation signal. Other variables, for example the tuning sensitivity of a voltage controlled oscillator associated with the phase locked loop, may vary in practical loops. All of these factors contribute to modulation distortion and the need to compensate for this distortion. One known technique is using a filter to shape a modulation signal prior to modulating a loop, however this often does not provide sufficient compensation for many systems. Other approaches use an adaptive filter but these require training times and some systems may not have the time or processing resources for the training.

### BRIEF DESCRIPTION OF THE DRAWINGS

The accompanying figures, where like reference numerals refer to identical or functionally similar elements throughout the separate views and which together with the detailed description below are incorporated in and form part of the specification, serve to further illustrate various embodiments and to explain various principles and advantages all in accordance with the present invention.

FIG. 1 depicts, in an exemplary transmitter including a simplified block diagram of an exemplary embodiment of a phase locked loop with modulation distortion compensation system according to the present invention;

FIG. 2 and FIG. 3 depict a more detailed block diagram of alternative exemplary embodiments of a phase locked loop and modulation distortion compensation system according to the present invention;

FIG. 4 illustrates a generalized architecture of an infinite impulse filter that may be utilized in one or more embodiments of a modulation distortion compensation system in accordance with the present invention;

FIG. 5 illustrates a graph of magnitude and group delay modulation response for one embodiment of a phase locked loop;

FIG. 6 illustrates a graph of magnitude and group delay response required to compensate for the FIG. 5 response;

FIG. 7 shows a table of expected results for modulation distortion for a single filter versus a plurality of filters; and

FIG. 8 illustrates filter selection versus a variety of variables associated with a phase locked loop.

### DETAILED DESCRIPTION

In overview, the present disclosure concerns communications equipment such as transmitters used in equipment and devices or units that are utilized to provide services for users thereof. More particularly various inventive concepts and principles embodied in apparatus and methods for providing or effecting compensation for phase locked loop modulation distortion for transmitters within communication equipment or units, where the phase locked loop systems operate to provide a radio frequency signal with modulation to transmitter amplifiers and the like are discussed and described. The systems and transmitters of particular interest are those being developed and deployed that use various forms of phase or complex modulation, i.e., modulation with a phase component, of a radio frequency signal to transfer information. In such transmitters a phase locked loop can be used to apply the modulation to the radio frequency carrier or signal and known problems with modulation distortion by the phase locked loop or synthesizer often need to be addressed. In some systems or equipment, e.g., frequency hopped systems utilized in Instrumentation, Scientific, and Medical (ISM) band or Family Radio Service (FRS) band, it is important that the compensation be efficient in terms of time or processing resources and the concepts and principles described herein may be particularly useful in these situations.

As further discussed below various inventive principles and combinations thereof are advantageously employed to select a filter response that corresponds, for example, to one or more of a tuning voltage associated with a phase locked loop or other environmental variables, e.g., power supply voltage or temperature and then predistort a modulation signal in accordance with the filter response and provide the resultant distorted signal to a modulation input, e.g., a feedback divider or loop divider input and thereby facilitate modulation and effect compensation for any modulation distortion resulting from the phase locked loop. This inventive compensation system and techniques can be particularly advantageously utilized in transmitters where carrier frequencies change often or where very little time or processing resources are available when a carrier frequency does change, thereby alleviating various problems associated with known compensation systems and facilitating lower cost higher performance transmitters, provided these principles or equivalents thereof are utilized.

The instant disclosure is provided to further explain in an enabling fashion, the best modes of making and using various embodiments in accordance with the present invention. The disclosure is further offered to enhance an understanding and appreciation for the inventive principles and advantages thereof, rather than to limit in any manner the invention. The invention is defined solely by the appended claims including any amendments made during the pendency of this application and all equivalents of those claims as issued.

It is further understood that the use of relational terms, if any, such as first and second, top and bottom, and the like are used solely to distinguish one from another entity or action without necessarily requiring or implying any actual such relationship or order between such entities or actions.

Much of the inventive functionality and many of the inventive principles are best implemented with or in integrated circuits (ICs) using hardware or hardware and software or firmware instructions, such as custom or semi-custom ICs, e.g., application specific ICs, that include a processing or digital signal processing function. It is expected that one of ordinary skill, notwithstanding possibly significant effort and many design choices motivated by, for example, available time, current technology, and economic considerations, when guided by the concepts and principles disclosed herein will be readily capable of generating such instructions and ICs with minimal experimentation. Therefore, in the interest of brevity and minimization of any risk of obscuring the principles and concepts according to the invention, further discussion of such software and ICs, if any, will be limited to the essentials with respect to the principles and concepts of the preferred embodiments

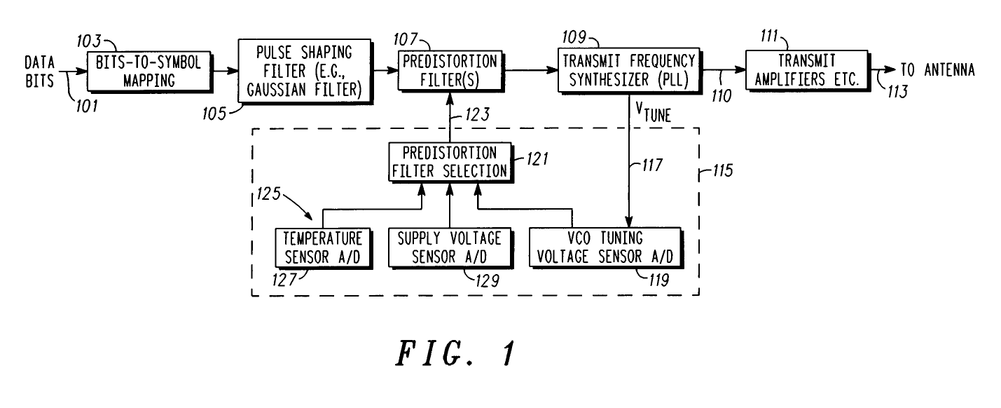

Referring to FIG. 1, an exemplary transmitter including a simplified block diagram of an exemplary embodiment of a phase locked loop with modulation distortion compensation system according to the present invention will be discussed and described. The transmitter, etc. of FIG. 1 depicts in a generalized manner various processing functions starting with DATA bits at an input 101 that is mapped to symbols for transmission at a symbol mapper or encoder 103. The output stream of symbols is applied to a pulse shaping filer 105. The pulse shaping filter is known and will vary with the particulars of the modulation but generally operates to round off any corners and thus attenuate corresponding higher frequency components of the symbol stream. Often a Gaussian filter, e.g., a finite impulse response (FIR) filter with a Gaussian shaped response will be specified by an underlying system standard or utilized by designers of proprietary systems.

As will be further described below, the output of the pulse shaping filter 105 is a modulation signal and is applied to a filter 107, i.e., a predistortion or compensation filter, where the response of this filter is selected from a plurality of filter responses. The output of the filter is a distorted signal or predistorted modulation signal that is coupled to a transmit frequency synthesizer or phase locked loop (PLL) and used facilitate modulation of the PLL or specifically voltage controlled oscillator (VCO) that is part of the PLL and to effect compensation for modulation distortion resulting from the PLL characteristics or variations within components of the PLL. The output 110 of the PLL 109 includes a radio frequency signal that can be centered, e.g., at the carrier frequency, and includes modulation where any modulation distortion (amplitude or group delay) has been reduced or compensated for by the distorted signal. This radio frequency signal will be processed by various additional known transmitter functions, e.g., transmit amplifiers, etc. 111 and applied to an antenna 113.

Also shown in FIG. 1, is a compensation function 115. The modulation distortion compensation system includes the compensation function 115 and the filter(s) 107. The compensation function 115 is coupled to a tuning voltage output 117 and thus a tuning voltage signal. The compensation function in various embodiments is configured to select a filter response from a plurality of filter responses, where the filter response is selected in accordance with one or more of a tuning voltage signal at the tuning voltage output 117 and an environmental signal, e.g., a supply voltage signal or temperature signal. The compensation function in some embodiments includes a tuning voltage sensor (ADC) 119 that is coupled to a filter selection function 121. The filter selection function is coupled at 123 to the filter 107 and operates to insure that the filter response that has been selected is implemented by the filter 107. The compensation function in additional embodiments includes environmental measuring functions 125 or sensors with a temperature function 127 and supply voltage function 129 each with outputs coupled to the filter selection function 121.

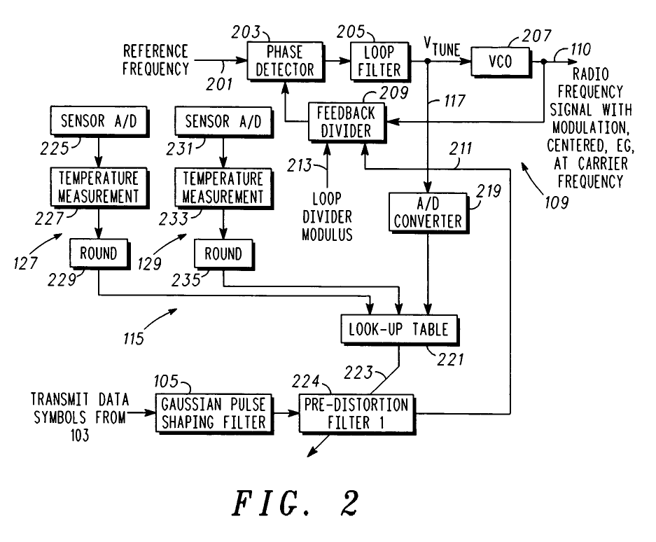

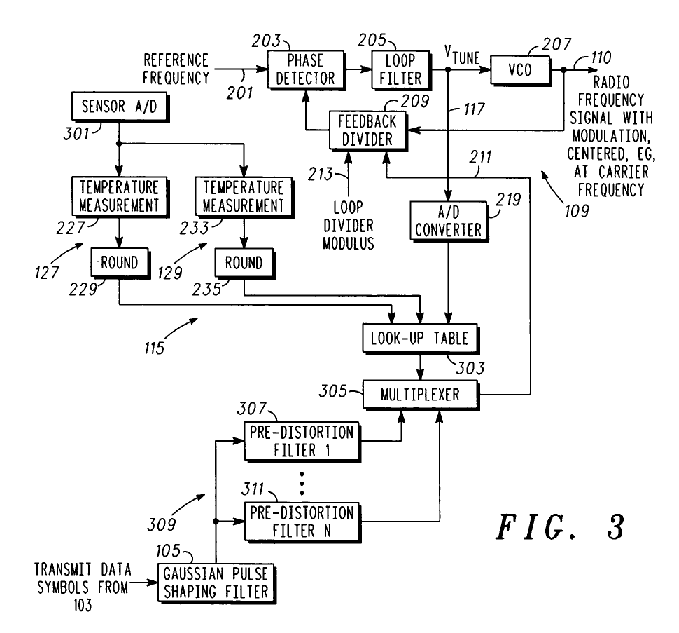

Referring to FIG. 2 and FIG. 3, more detailed block diagrams of alternative exemplary embodiments of a phase locked loop and modulation distortion compensation system according to the present invention, will be briefly discussed and described.

FIG. 2 illustrates the PLL 109 in more detail. As depicted, a reference signal at 201 is input to a phase detector 203 which is coupled to a loop filter 205 that has a tuning voltage output 117. Typically the reference signal is supplied by a crystal oscillator and a reference divider (not shown). The tuning voltage output is coupled to a VCO 207 that operates to provide a radio frequency signal with a frequency corresponding to the tuning voltage at 110, where this signal includes modulation and may be centered at, e.g., a carrier frequency. The signal out of the VCO is coupled to a feedback divider 209 that has a modulation input 211 and is configured to be programmed by a divider modulus at 213. The output of the feedback divider or loop divider is coupled to the phase detector 203.

Generally the operation of a PLL is known and the literature is replete with references for those who are interested or desire a more detailed review. Essentially the phase detector outputs a signal corresponding to a phase difference between the reference signal and the signal at the output of the feedback divider. This signal is filtered by the loop filter and applied to the VCO. The frequency of the radio frequency signal from the VCO is divided down by the feedback divider according to the divider modulus or divisor. Due to the feedback loop, any difference between the frequency of the signals at the inputs to the phase detector will be eliminated since the phase difference would otherwise grow without bound. The frequency of the signal at the output of the VCO will be equal to the reference frequency multiplied by the divisor or divider modulus of the feedback divider. Many PLLs today use so called fractional (frac) N feedback dividers and these operate as is known to effectively implement a non integer, e.g., 10,000.5, divisor in the feedback divider. Generally a frac N divider switches between different divisors and the proportion of time the divider is operating with one divisor versus other divisors determines the effective divisor.

Frac N dividers may also be used to frequency or phase modulate the radio frequency signal by essentially changing the effective divider modulus in accordance with the modulating signal. Those or ordinary skill will realize that frequency components of the modulation signal as reflected at the output of the feedback divider and thus phase detector will modulate the VCO output signal frequency only to the extent these frequency components are allowed to pass through the loop filter. In many practical systems the loop filter bandwidth will be on the order of the modulation signal bandwidth and thus the loop filter magnitude and phase response can be a significant contributing factor to modulation distortion.

Another source of modulation distortion is a VCO. As the desired channel or carrier frequency changes, the tuning voltage required to drive the VCO to provide this signal frequency also changes. Typical VCOs will also experience a change in tuning voltage sensitivity (normally expressed in MHz/volt units) as a function of the tuning voltage. For example in one embodiment, as the tuning voltage varies from a minimum to a maximum, e.g., 0.5. volts to 2.0 volts, the tuning sensitivity of the VCO more than doubles, e.g., 6 MHz/volt to 14 MHz/volt. When a modulation signal is applied and a certain change in frequency is expected, this change in tuning sensitivity means that the change in frequency will vary widely depending on what channel or carrier frequency is being provided by the VCO. Other reasons for or causes of modulation distortion, such as changes in environmental variables (temperature, supply voltage, etc.) or loop gains, etc. may also need to be taken into consideration. Compensation systems for mitigation of modulation distortion can be used to reduce the amount of the modulation distortion.

One or more embodiments of modulation distortion compensation system for use with the PLL is shown in FIG. 2. The PLL 109 comprising the phase detector 203, the loop filter 205 including the tuning voltage output 117, the voltage controlled oscillator (VCO) 207 configured to provide the modulated radio frequency signal at 110, and the feedback divider 209 with the modulation input 211 are all intercoupled as a phase locked loop where compensation for modulation distortion may be needed. A compensation function 115 (P/O the distortion compensation system) is coupled to the tuning voltage output 117 and is configured to select a filter response from a plurality of filter responses, where the filter response is selected in accordance with at least a tuning voltage signal at the tuning voltage output. For example, in one embodiment the compensation function further comprises an analog to digital converter 219 that is coupled to the tuning voltage output and configured to convert the tuning voltage signal to a digital tuning voltage signal and a look up table 221. The digital tuning voltage signal is used to facilitate access to the lookup table to select one or more parameters associated with the filter response. Note that the analog to digital converter 219 may also include a register, etc. and rounding operation if needed, similar to the arrangements noted below with reference to various environmental functions. However since the tuning voltage in a given application is likely to be well known and carefully characterized, a simple ADC that provides a relatively small digital word, e.g., a 3 bit word, can be sufficient for many applications. It is also noted that the tuning voltage output is shown as directly connected to the loop filter and VCO junction, however in practice due to the susceptibility of this junction to noise and interference various isolation stages will normally be present between the loop filter and the tuning voltage output and it may be appropriate to only enable the tuning voltage output when an updated distortion filter response is indicated (e.g., every time the PLL changes frequencies or reacquires lock or the like).

The modulation distortion compensation system also comprises a filter 224, operationally analogous to the filter 107, that is configured to distort a modulation signal, e.g., transmit data symbols from 103 as shaped by the shaping filter 105, in accordance with the filter response and provide a distorted signal to the modulation input 211. The distorted signal or predistorted modulation signal can be used by the feedback divider in the phase locked loop to facilitate modulation of the VCO and effect compensation for or reduce or mitigate modulation distortion resulting from the phase locked loop, whether due to the dynamics of the PLL or variations in its constituent components.

The filter in certain embodiments includes a digital filter with programmable coefficients and the compensation function is configured to select the filter response by providing coefficients, e.g., predetermined coefficients, for the digital filter that correspond to the filter response. In other embodiments, such as those shown in FIG. 3, the modulation distortion compensation system further comprises a multiplexer coupled to the compensation function and the filter further comprises a plurality of filters each with a unique filter response corresponding to one of the plurality of filter responses. As further discussed below, the compensation function is then configured to select the filter response by providing a select signal to the multiplexer.

In one or more embodiments, the compensation function further comprises one or more environmental measuring functions 125, such as a temperature measuring function 127 configured to provide a temperature signal or power supply voltage measuring function 129 configured to provide a voltage signal. The filter response in these instances will be selected in accordance with the tuning voltage signal and one or more of the temperature signal and the voltage signal.

The temperature measuring function 127 in some embodiments further comprises an analog to digital converter 225 with an input for receiving a temperature indication, e.g., from a device or sensor or the like (PN junction varies about 2.2 milli volts per degree Celsius) and an output for providing a digital temperature indication. The digital temperature indication is provided to a temperature converter 227 for converting the digital temperature indication to the temperature signal, where the temperature signal comprises in some embodiments a digital temperature signal. Note the temperature converter may be as simple as a register for storing a digital word, e.g., an 8 bit word, but can also represent any normalization or calibration processes that may be desired. The output of the converter 227 is shown coupled to a rounding operation 229 where the digital word can be rounded off as needed, e.g., the 8 bit word can be converted to a 4 bit word corresponding to a 4 bit rounded version of the 5 most significant bits. The resultant temperature signal is coupled to the look up table 221 and can be used in conjunction with the tuning voltage signal to select a frequency response.

Similarly, the power supply voltage measuring function further comprises an analog to digital converter 231 with an input for receiving a power supply voltage indication and an output for providing a digital voltage indication. The digital voltage indication is provided to a voltage converter 233 for converting the digital voltage indication to the voltage signal. Again this can be a register for storing a digital word and may include normalization and calibration processes. Thus the voltage signal comprises a digital voltage signal and may also be sent through a rounding operation 235 where, e.g., an 8 bit word is rounded to a 3 bit voltage signal and the resultant voltage signal is coupled to the look up table 221 and can be used in conjunction with the tuning voltage signal, temperature signal, etc. to select a frequency response.

Given the tuning voltage signal, temperature signal, or voltage signal or a particular combination of these signals, as an address to the look up table, access to a particular location in the look up table 221 can provide one or more parameters associated with a desired filter response. For example, predetermined filter coefficients can be stored at that location and provided at output 223. These predetermined filter coefficients can be used to configure the predistortion filter 224. Given that an IIR filter is one embodiment of a suitable filter and possibly as many as 8 coefficients (4 numerator and 4 denominator coefficients) each 32 bits long may be needed to implement an IIR filter that provides a proper response, the look up table can become relatively large, if each of the possible locations available with a 10 bit address contains these 8 coefficients. However using this approach allows a large number of predetermined filter responses to be made available if that is required in order to sufficiently compensate for the modulation distortion. Similarly, if an FIR filter architecture is used, the number of taps required can be approximately 40 taps where each tap may require approximately 16 bits to define.

In an alternative embodiment, access to a particular location in the look up table can provide an indication of one set predetermined filter coefficients out of a plurality or multitude of such sets with the indication provided at output 223. The indication would be used to select the one set from various such sets and program or configure the filter 224. For example, if a small number (relative to the 10 bit address range of the look up table) of predetermined filter responses is deemed sufficient to provide compensation, each location in the look up table can be populated with an indication for one of the small number of filter responses, i.e., 000, 001, 010, 011, . . . , where each of these 3 bit words indicates a particular set of predetermined filter coefficients. The indication would be used to select via a multiplexer or the like (not specifically shown in FIG. 2) the proper set of filter coefficients and configure the filter 224 accordingly.

FIG. 3 illustrates an alternative embodiment of the modulation distortion compensation system for a phase locked loop. Generally the various functions or features of FIG. 3 are similar to FIG. 2 except where indicated by a 3xx reference numeral. The description and discussion of FIG. 3 will generally be limited to those elements or features that are new except that a summary of the concepts and inventive principles will be provided in closing. FIG. 3 shows a sensor ADC 301 that may be shared among various environmental sensors in order to convert various environmental indications to corresponding signals, e.g., temperature signals and voltage signals.

A look up table 303 is coupled to various signals, e.g., a tuning voltage signal, temperature signal, and supply voltage signal that are used to form an address that allows access to a particular location in the look up table. In this look up table an indication, e.g., 3 bit word or the like, much as described above for a particular predetermined filter response and thus filter is stored at each location in the table. This indication is provided at output 304 to a multiplexer 305. The multiplexer then couples the output of one filter (filter1 307, . . . filterN 311) out of a multitude of filters 309, where the one filter corresponds to the indication from the look up table, to the modulation input 211. In situations where the compensation system must be modified and begin acting quickly the approach of FIG. 3 may be preferred. Since the filters are digital filters and can be implemented as firmware instructions executed by a digital signal processor or the like or in other embodiments implemented in hardware these filters can essentially be operating on a continuous basis and thus any delay associated with configuring the filter and reaching a steady state will not be encountered in simply switching the appropriate filter output to the modulation input.

As a brief review FIG. 1-FIG. 3 and the discussions above have described the inventive concepts and principles corresponding to a novel modulation distortion compensation system for a phase locked loop. The modulation distortion compensation system includes a compensation function 115 arranged to be coupled to a tuning voltage signal corresponding to a tuning voltage from the phase locked loop and configured to select a filter response from a plurality of filter responses, where the filter response corresponds to the tuning voltage. Further included is filter 307, 309, 311 that is configured to distort a modulation signal in accordance with the filter response and provide a distorted signal suitable for being coupled to a modulation input of a feedback divider included with the phase locked loop. This distorted signal when used by the feedback divider will facilitate modulation and compensation of a radio frequency signal provided by the phase locked loop.

The compensation function in certain embodiments further comprises an analog to digital converter arranged to be coupled to the tuning voltage signal and configured to convert the tuning voltage signal to a digital tuning voltage signal; and a look up table, the digital tuning voltage signal used to facilitate access to the lookup table to select one or more parameters associated with the filter response. The compensation function can include an environmental measuring function configured to provide an environmental signal, where the filter response is selected in accordance with the environmental signal and the tuning voltage signal.

The environmental measuring function can include a temperature measuring function or supply voltage measuring function each configured to provide, respectively a temperature signal or voltage signal. The filter response is then selected in accordance with the temperature signal, the voltage signal and the tuning voltage signal. The temperature measuring function and supply voltage measuring function each comprise either a shared or an individual analog to digital converter with an input for receiving a temperature indication or supply voltage indication and an output for providing a digital temperature or digital voltage indication; and a temperature or voltage converter for converting the digital temperature or voltage indication to the temperature or voltage signal, respectively.

The filter for the modulation distortion compensation system in various embodiments further comprises a digital filter with programmable coefficients and the compensation function is configured to select the filter response by providing coefficients for the digital filter that correspond to the filter response. In one embodiment, the modulation distortion compensation system further comprises a multiplexer coupled to the compensation function and the filter includes a plurality or multitude of filters each with a unique filter response corresponding to one of the plurality of filter responses. The compensation function is configured to select the filter response by providing a select signal to the multiplexer.

Referring to FIG. 4, a generalized architecture of an infinite impulse response (IIR) filter that may be utilized in one or more embodiments of a modulation distortion compensation system in accordance with the present invention will be briefly described and discussed. The filter 400 of FIG. 4 illustrates the numerator coefficients (b0, b1, . . . bN−1 401) and the denominator coefficients (a0, a1, . . . aN−1 403) that may be chosen to adapt the location of zeros and poles such that a desired filter response can be obtained as is generally known. The filter 400 is suitable for utilization as any of the filters 307, 309, 311 of FIG. 3, filter 224 of FIG. 2, or filter 107 of FIG. 1. While an IIR filter has been shown it is equally plausible to use a FIR filter architecture.

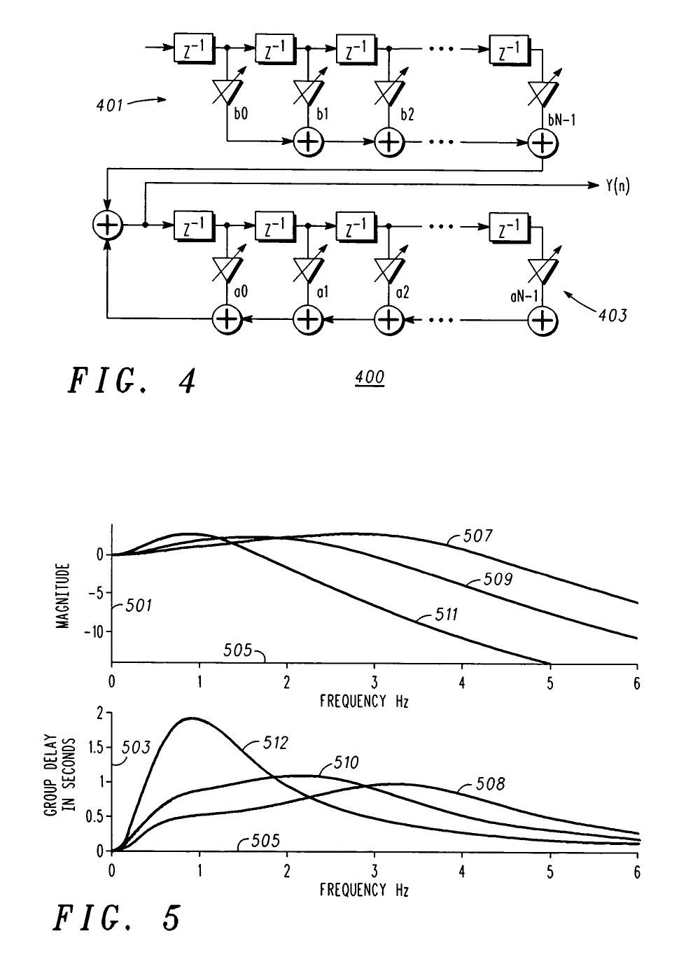

Referring to FIG. 5, a graph of magnitude and group delay modulation response for one embodiment of a phase locked loop is shown and will be briefly discussed and described. Generally, FIG. 5 is indicative of the modulation distortion that needs to be addressed. FIG. 5 illustrates one embodiment of a phase locked loop for three different magnitude and group delay responses of the closed loop phase locked loop system. These include a “max case” with −3 dB magnitude corner at 42 KHz, a “typical case” with a −3 dB magnitude corner at 30 KHz, and a “min case” with a −3 dB magnitude corner at 16.5 KHz. Generally FIG. 5 shows magnitude 501 and group delay 503 as a function of modulation signal frequency 505. A modulation signal with a given amplitude is applied to the phase locked loop and the frequency of this modulating signal is varied from 0 Hz to 60 KHz. The resultant frequency modulation of a radio frequency signal is measured and the magnitude and group delay are plotted in FIG. 5.

Note that the three different situations (max, typical, min) are plotted for each of the magnitude and group delay. The maximum situation, corresponding to curves 507, 508, represents a simulated situation where all factors (loop gain, tuning sensitivity, temperature, supply voltage, etc) assume a more or less worst case maximum situation. The typical situation, corresponding to curves 509, 510, represents a simulated situation where all factors (loop gain, tuning voltage sensitivity, temperature, supply voltage, etc) assume a more or less typical situation. The minimum situation, corresponding to curves 511, 512, represents a simulated situation where all factors (loop gain, tuning sensitivity, temperature, supply voltage, etc) assume a more or less worst case minimum situation. If there was no modulation distortion, the magnitude curves would be flat at least across the bandwidth of interest, e.g., a channel bandwidth, and the group delay curve would be a straight line with a given slope.

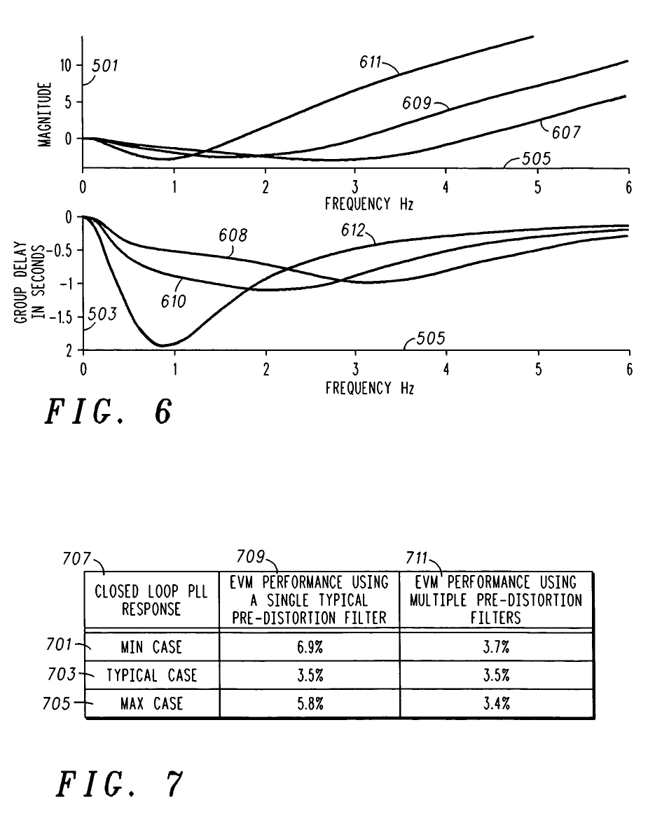

Referring to FIG. 6, a graph of magnitude and group delay response required from a filter in order to compensate for the FIG. 5 response (modulation distortion) is shown and will be briefly discussed and described. Generally a magnitude and group delay curve is shown for each of the maximum, minimum, and typical situations discussed with reference to FIG. 5. In FIG. 6 if a filter had the magnitude 607 and group delay 608 response it would fully compensate for the modulation distortion shown by curves 507, 508. Similarly a filter or predistortion filter with magnitude 609, and group delay 610 response would compensate for the modulation distortion shown by curves 509, 510 and a filter with magnitude 611 and group delay 612 response would compensate for modulation distortion as reflected by curves 511, 512. One of ordinary skill could of course plot additional curves in between the maximum and minimum curves as needed and derive filter coefficients for the appropriate compensation filter.

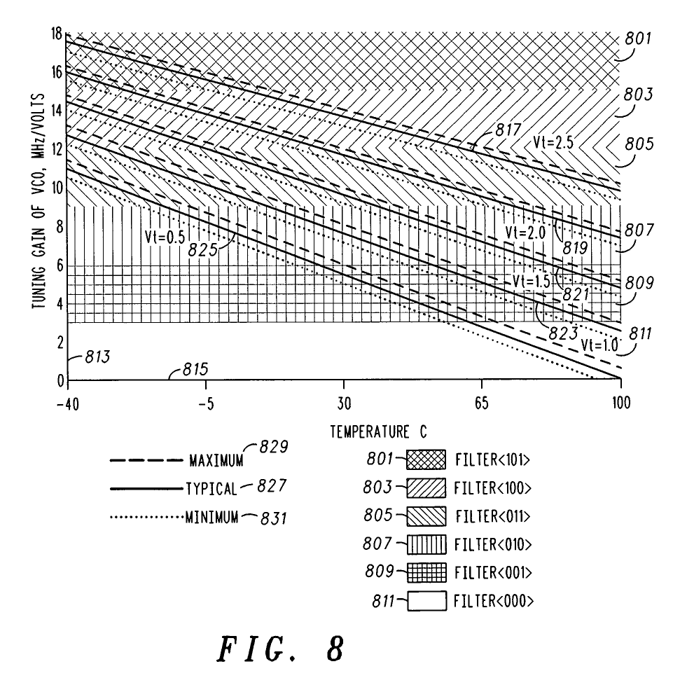

Referring to FIG. 7, a table of expected (simulated) results for modulation distortion for a single filter versus a multitude of filters, e.g., six filters, is shown and will be briefly discussed and described. The table 700 reflects the min 701, typical 703, and max 705 PLL response cases 707. For each of these cases an Error Vector Magnitude (EVM) is listed for a single predistortion filter case 709 and for multiple predistortion filters 711, i.e., where the appropriate filter of the multitude is chosen. It should be noted that the objective was to provide less than 5% EVM across all variables. EVM is a way of quantizing modulation distortion and is essentially the magnitude of the difference in percent between an actual vector and a desired or ideal vector when a given input data bit stream is used to modulate a radio frequency signal. Said another way EVM measurements are done by measuring the root mean square error between signals processed via an ideal and a non-ideal or actual signal path using a given input data bit stream to generate the signals. By observation as would be expected when a single filter is used and set to compensate for the typical case a multitude of filters with a filter set for the typical case performs the same. However in both the min 701 and max 705 cases, the EVM performance when an appropriate filter from the multitude of filters is used a significant improvement is realized and the results are within the desired 5% limits. The results are not within the desired limit for the single filter case because the nominal or typical predistortion filter “over-compensates” for the min case and “under-compensates” for the max case. Note that the modulation distortion cases located between the min, typical, and max cases in FIG. 5 can be effectively compensated for with appropriate selection of the min, typical, and max predistortion filters based on the measured tuning voltage, temperature, and supply voltage measurements to achieve less than 5% EVM for this example case.

Referring to FIG. 8, the appropriate filter selection in one embodiment versus a variety of variables (tuning voltage, temperature, and power supply voltage) associated with a phase locked loop is shown and will be briefly discussed and described. Generally FIG. 8 shows a graph of VCO tuning gain on the vertical axis 813 and temperature on the horizontal axis 815. The area of the graph is broken into, in this embodiment, 6 equally spaced regions 801, 803, . . . 811, where these regions correspond to one of six unique filters with associated and predetermined filter coefficients. The graph also shows tuning voltages as lines. A tuning voltage of 2.5, 2.0, 1.5, 1.0, and 0.5 volts corresponds to lines 817, 819, . . . , 825, respectively. These lines also correspond to a typical supply voltage. Each of these tuning voltage lines is bordered on the top by a line representing a maximum supply voltage 829 and on the bottom by a line representing a minimum supply voltage 831. Thus the proper filter to select can be found by finding the tuning voltage, temperature, and supply voltage and then using the filter corresponding to the region where these variables intersect. For example, for a temperature of 30 degrees and a tuning voltage of 1.0 volts, regardless of power supply voltage, filter <010> corresponding to region 807 should be used.

There are various techniques available to generate the filter coefficients, i.e., digital predistortion filter coefficients. For example, an IIR filter can be designed to perform the inverse response of the closed loop PLL system or an FIR filter can be designed using adaptive equalization techniques (such as Recursive Least Squares methods) to equalize for the magnitude and group delay distortion of the PLL over the modulated signal bandwidth. The important thing to remember is that these filter coefficients should be predetermined or pre-calculated and stored in memory in order to have a multitude of filter responses available, i.e. multiple predetermined filter responses are available. This gives the advantage of multiple filters in terms of EVM improvement as compared to a single compensation filter and also avoids the system overhead and timing delays associated with training procedures and the like when an adaptive filter is used.

Thus a method of facilitating compensation for modulation distortion in a phase locked loop, and corresponding compensation systems and apparatus have been described and disclosed where the method includes providing a tuning voltage from the phase locked loop, selecting, responsive to the tuning voltage, a filter response from a plurality of filter responses; and filtering a modulation signal in accordance with the filter response to provide a distorted signal, such that the distorted signal is suitable for modulation and compensation of a radio frequency signal provided by the phase locked loop.

In various embodiments, this includes converting the tuning voltage to a digital tuning voltage signal and using the digital tuning voltage signal to facilitate access to a memory to select one or more parameters associated with the filter response. Other embodiments additionally include providing one or more environmental signals associated with corresponding environmental conditions and selecting the filter response in accordance with the tuning voltage signal and the one or more environmental signals.

A modulation distortion compensation system for a PLL used, for example, in a transmitter, is arranged and constructed to mitigate or compensate for modulation distortion via a predistorted signal. The system uses pre-determined or pre-calculated filter parameters or coefficients to provide a selected one of a plurality of filter responses and a tuning voltage or environmental signals to guide the selection of the appropriate one of the filter responses. The selected filter response is used to predistort the modulation signal and thus compensate for modulation distortion of the PLL as has been discussed and described.

This disclosure is intended to explain how to fashion and use various embodiments in accordance with the invention rather than to limit the true, intended, and fair scope and spirit thereof. The foregoing description is not intended to be exhaustive or to limit the invention to the precise form disclosed. Modifications or variations are possible in light of the above teachings. The embodiment(s) was chosen and described to provide the best illustration of the principles of the invention and its practical application, and to enable one of ordinary skill in the art to utilize the invention in various embodiments and with various modifications as are suited to the particular use contemplated. All such modifications and variations are within the scope of the invention as determined by the appended claims, as may be amended during the pendency of this application for patent, and all equivalents thereof, when interpreted in accordance with the breadth to which they are fairly, legally, and equitably entitled.

What is claimed is:

1. A phase locked loop with modulation distortion compensation system comprising:
a phase detector, a loop filter including a tuning voltage output, a voltage controlled oscillator (VCO) configured to provide a modulated radio frequency signal, and a feedback divider with a modulation input all intercoupled as a phase locked loop;
a compensation function coupled to the tuning voltage output and configured to select a filter response from a plurality of filter responses, the filter response selected in accordance with a tuning voltage signal at the tuning voltage output; and
a filter configured to distort a modulation signal in accordance with the filter response and provide a distorted signal to the modulation input, the distorted signal used by the feedback divider in the phase locked loop to facilitate modulation of the VCO and effect compensation for modulation distortion resulting from the phase locked loop.

2. The phase locked loop with modulation distortion compensation system of claim 1 wherein the compensation function further comprises:
an analog to digital converter coupled to the tuning voltage output and configured to convert the tuning voltage signal to a digital tuning voltage signal; and
a look up table, the digital tuning voltage signal used to facilitate access to the lookup table to select one or more parameters associated with the filter response.

3. The phase locked loop with modulation distortion compensation system of claim 1 wherein the compensation function further comprises a temperature measuring function configured to provide a temperature signal, the filter response selected in accordance with the temperature signal and the tuning voltage signal.

4. The phase locked loop with modulation distortion compensation system of claim 3 wherein the temperature measuring function further comprises:
an analog to digital converter with an input for receiving a temperature indication and an output for providing a digital temperature indication; and
a temperature converter for converting the digital temperature indication to the temperature signal, the temperature signal comprising a digital temperature signal.

5. The phase locked loop with modulation distortion compensation system of claim 1 wherein the compensation function further comprises a power supply voltage measuring function configured to provide a voltage signal, the filter response selected in accordance with the voltage signal and the tuning voltage signal.

6. The phase locked loop with modulation distortion compensation system of claim 5 wherein the power supply voltage measuring function further comprises:
an analog to digital converter with an input for receiving a voltage indication and an output for providing a digital voltage indication; and
a voltage converter for converting the digital voltage indication to the voltage signal, the voltage signal comprising a digital voltage signal.

7. The phase locked loop with modulation distortion compensation system of claim 1 further comprising a multiplexer coupled to the compensation function and wherein the filter further comprises a plurality of filters each with a unique filter response corresponding to one of the plurality of filter responses, the compensation function configured to select the filter response by providing a select signal to the multiplexer.

8. The phase locked loop with modulation distortion compensation system of claim 1 wherein the filter further comprises a digital filter with programmable coefficients and the compensation function is configured to select the filter response by providing coefficients for the digital filter that correspond to the filter response.

9. A modulation distortion compensation system for a phase locked loop, the modulation distortion compensation system comprising:
a compensation function arranged to be coupled to a tuning voltage signal corresponding to a tuning voltage from the phase locked loop and configured to select a filter response from a plurality of filter responses, the filter response corresponding to the tuning voltage; and
a filter configured to distort a modulation signal in accordance with the filter response and provide a distorted signal suitable for being coupled to a modulation input of a feedback divider included with the phase locked loop, wherein the distorted signal when used by the feedback divider will facilitate modulation and compensation of a radio frequency signal provided by the phase locked loop.

10. The modulation distortion compensation system of claim 9 wherein the compensation function further comprises:
an analog to digital converter arranged to be coupled to the tuning voltage signal and configured to convert the tuning voltage signal to a digital tuning voltage signal; and
a look up table, the digital tuning voltage signal used to facilitate access to the lookup table to select one or more parameters associated with the filter response.

11. The modulation distortion compensation system of claim 9 wherein the compensation function further comprises an environmental measuring function configured to provide an environmental signal, the filter response selected in accordance with the environmental signal and the tuning voltage signal.

12. The modulation distortion compensation system of claim 11 wherein the environmental measuring function further comprises a temperature measuring function configured to provide a temperature signal, the filter response selected in accordance with the temperature signal and the tuning voltage signal.

13. The modulation distortion compensation system of claim 12 wherein the temperature measuring function further comprises:
an analog to digital converter with an input for receiving a temperature indication and an output for providing a digital temperature indication; and
a temperature converter for converting the digital temperature indication to the temperature signal, the temperature signal comprising a digital temperature signal.

14. The modulation distortion compensation system of claim 11 wherein the environmental measuring function further comprises a voltage measuring function configured to provide a voltage signal, the filter response selected in accordance with the voltage signal and the tuning voltage signal.

15. The modulation distortion compensation system of claim 14 wherein the voltage measuring function further comprises:
an analog to digital converter with an input for receiving a voltage indication and an output for providing a digital voltage indication; and
a voltage converter for converting the digital voltage indication to the voltage signal, the voltage signal comprising a digital voltage signal.

16. The modulation distortion compensation system of claim 9 further comprising a multiplexer coupled to the compensation function and wherein the filter further comprises a plurality of filters each with a unique filter response corresponding to one of the plurality of filter responses, the compensation function configured to select the filter response by providing a select signal to the multiplexer.

17. The modulation distortion compensation system of claim 9 wherein the filter further comprises a digital filter with programmable coefficients and the compensation function is configured to select the filter response by providing coefficients for the digital filter that correspond to the filter response.

18. A method of facilitating compensation for modulation distortion in a phase locked loop, the method comprising:
providing a tuning voltage from the phase locked loop;
selecting, responsive to the tuning voltage, a filter response from a plurality of filter responses; and
filtering a modulation signal in accordance with the filter response to provide a distorted signal, the distorted signal suitable for modulation and compensation of a radio frequency signal provided by the phase locked loop.

19. The method of claim 18 further comprising:
converting the tuning voltage to a digital tuning voltage signal; and
using the digital tuning voltage signal to facilitate access to a memory to select one or more parameters associated with the filter response.

20. The method of claim 18 further comprising:
providing one or more environmental signals associated with corresponding environmental conditions; and
selecting the filter response in accordance with the tuning voltage signal and the one or more environmental signals.
